(19) United States
(12) Patent Application Publication
(10) Pub. No.: US 2004/0169557 A1
(43) Pub. Date: Sep. 2, 2004

(54) Signal processing apparatus

(76) Inventors: Peter Kenington, Chepstow (GB); Steven Meade, Bristol (GB); John Bishop, Bristol (GB)

Correspondence Address: MENDELSOHN AND ASSOCIATES PC, 1515 MARKET STREET, SUITE 715, PHILADELPHIA, PA, 19102, US

(21) Appl. No.: 10/476,295

(22) PCT Filed: Apr. 30, 2002
(86) PCT No.: PCT/GB02/01969

(30) Foreign Application Priority Data
Apr. 30, 2001 (GB) 0110559.2

(51) Int. Cl. H03F 1/26

(52) U.S. Cl. 330/149

(57) ABSTRACT

Where a DSP is used to predistort the input to a radio frequency power amplifier (RF PA) in the digital domain, then the DSP can also be used to perform a mathematical clipping operation on the input signal. This means that unwanted distortion is not introduced via the clipping process.

The invention relates to apparatus for conditioning input signals for amplifiers, particularly power amplifiers.

Telecommunications transmitters are subject to adjacent channel power (ACP) requirements which dictate that the amplification of the power of signals to be transmitted must be undertaken in an extremely linear manner, i.e. distortion created by the power amplification process must be kept to a minimum. Commonly, a predistorter is used with a power amplifier to ensure that the output of the latter remains linear in order to satisfy the ACP requirements.

It is desirable to constrain the ratio of peak to mean power of a power amplifier in a transmitter in order to enhance the efficiency of the amplification process. Commonly, the ratio of peak power to mean power (“the peak to mean ratio”) is constrained by clipping the signals being amplified. There are two common ways of performing clipping. The first way involves providing a low power RF limiter circuit (e.g. using pair of diodes) which clips the input signal. The second way is to allow the power amplifier itself to saturate and thereby limit the amplitude of its output signal. Both of these two approaches introduce substantial additional non-linearity into the amplifier characteristic and therefore reduce tie mean power at which the amplification system can operate whilst meeting ACP requirements. In turn, this leads to a reduction in the power efficiency obtainable from the amplification system and an increase in the size of tie power amplifier required to achieve a given mean output power.

An aim of the invention is to provide a better way of amplifying signals.

According to one aspect, the invention provides apparatus for conditioning an input signal to an amplifier, comprising signal processing means for operating on the input signal in the digital domain, wherein the signal processing means is arranged to predistort the input signal and is also arranged to clip the input signal.

Thus, the invention allows the clipping to be performed digitally which means that less distortion is generated. Furthermore, the invention provides that, in an arrangement where digital signal processing means is provided to predistort an input signal, then the signal processing means can additionally perform the clipping without additional components or circuitry being required. Because the invention reduces the amount of distortion created, a greater proportion of the system's effort is used in the amplification of wanted signals as opposed to unwanted distortion products. This means that the overall efficiency of the amplification process (including the clipping process) is enhanced, with the result that the size of an amplifier needed to meet any given power requirement is reduced.

In a preferred embodiment, the input signal is a radio frequency (RF) signal and the apparatus further comprises means for down converting the input signal's frequency before the signal processing means operates on the input signal. Advantageously, this reduces the clock rate or processing speed required of the signal processing means. Alternatively, the input signal could be at a low frequency, e.g. it could be a base band signal, so that the signal processing means can be supplied directly with the input signal, i.e. down conversion of the input signal is not required.

The apparatus may also comprise means for up converting the input signal's frequency after the signal processing means has operated on the input signal. For example, this may be used to up convert the input signal leaving the signal processing means to a frequency suitable for transmission.

In one embodiment, the signal processing means comprises a digital signal processor. In another embodiment, the signal processing means comprises a programmable logic device such as a field programmable gate array (FPGA). Alternatively, the signal processing means may comprise an application specific integrated circuit (ASIC).

The apparatus for conditioning an amplifying signal can be employed in a transmitter such as a telecommunications base station.

By way of example only, an embodiment of the invention will now be described with reference to the accompanying figures, in which:

FIG. 1 is a block diagram of a linearised RF power amplifier;

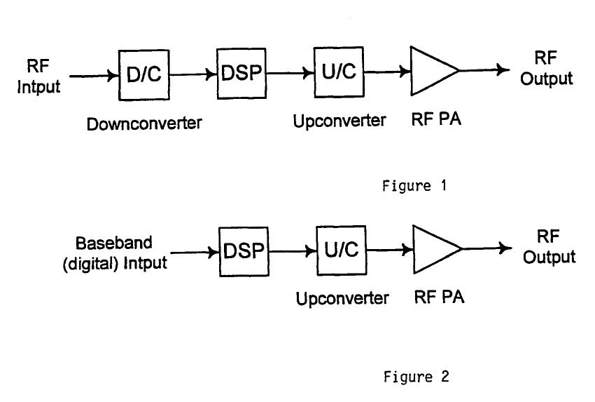

FIG. 2 is a block diagram of a digitally linearised transmitter;

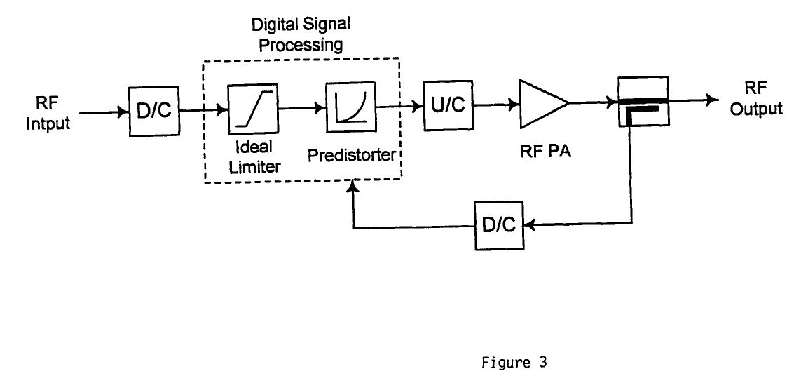

FIG. 3 is a block diagram of a linearised RF power amplifier comprising a clipping process; and

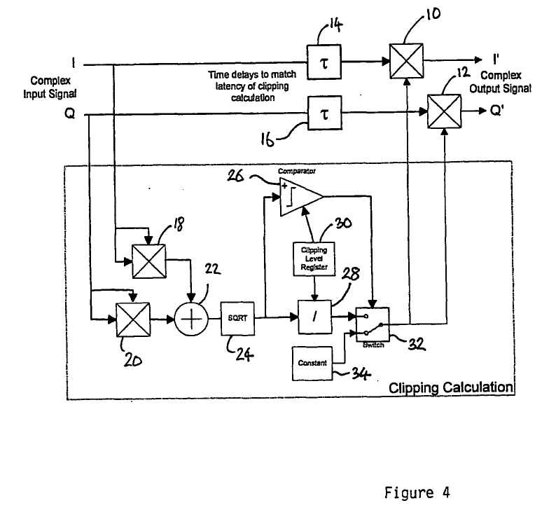

FIG. 4 is a block diagram of the clipping process employed in FIG. 3.

FIGS. 1 and 2 illustrate two different scenarios where the linearisation of a radio frequency power amplifier (RF PA) is required.

FIG. 1 illustrates a RF PA supplied with a RF input signal. As shown in FIG. 1, the RF input signal is down converted to a frequency that can be handled by the DSP. The down converted signal is converted to the digital domain and is predistorted within the DSP. The predistorted input signal for the amplifier is then converted back to the analogue domain and up converted to the desired transmission frequency (which may or may not be the same as the original RF input frequency) and is fed to the RF PA. The predistortion process implemented by the DSP counteracts the non-linearities within the RF PA to reduce distortion appearing in the RF output.

The system of FIG. 2 differs in that the input signal is at base band or at a digital IF rather than at RF. The input signal could be, for example, digitised speech uttered by a mobile telephone user. Since the input signal is at base band, down conversion is not required and the DSP predistorts the digital base band input signal directly. The output of the DSP is then converted to the analogue domain and up converted before being fed to the RF PA. The DSP functions to counteract non-linearities within the RF PA in much the same manner as described with reference to FIG. 1.

FIG. 3 illustrates how a clipping process can be added to the tasks performed by a digital signal processor which is already arranged to perform digital predistortion. FIG. 3 illustrates how the clipping process is incorporated in the scheme of FIG. 1, but it will be apparent to the skilled person how the clipping process could be implemented in a similar manner in the system of FIG. 2.

As before, the digital signal processor receives a low frequency digital version of the signal to be amplified. This signal is subjected to a clipping process (which will be described in more detail later) and then a predistortion process. The clipped and predistorted input signal then leaves the digital signal processor and is converted to an analogue signal at a desired transmission frequency and supplied to the RF PA. The output of the RF PA is sampled to provide a feedback signal for controlling the predistortion process performed within the digital signal processor. The frequency of the feedback signal is down converted to a data rate suitable for the digital signal processor.

The purpose of the clipping process is to limit the maximum amplitude attainable by the input signal. If the input signal amplitude is below the maximum attainable amplitude set by the clipping process, then the input signal amplitude is unchanged by the clipping process. However, if the input signal amplitude exceeds the maximum attainable amplitude set by the clipping process, then the clipping process operates to set the input signal amplitude to be equal to the maximum attainable amplitude. The operation of the clipping process is summarised by the following pseudo code listing:

If \sqrt{I²+Q²}Clipping Level, then scale I and Q signals such that

$${I}^{′} = {I}^{*} \frac{Clipping Level}{\sqrt{{I}^{2} + {Q}^{2}}}$$

$${Q}^{′} = {Q}^{*} \frac{Clipping Level}{\sqrt{{I}^{2} + {Q}^{2}}}$$

Else I′=I and Q′=Q

Of course, the foregoing pseudo code description assumes that the input signal is in Cartesian format comprising an in-phase (I) component and a quadrature (Q) component.

The block diagram of FIG. 4 explains the clipping process from a different view point, but nevertheless accords with the pseudo code description given above.

The input signal to the RF PA is provided to the clipping process in Cartesian components (conversion into this format being performed if required), each of which is multiplied by a scaling factor (at respective multipliers 10 and 12) to produce a clipped input signal comprising Cartesian components I′ and Q′. There is a time delay whilst the appropriate coefficients are calculated so the I and Q components are each subjected to a time delay (14 and 16 respectively) to ensure that the I and Q components are time-aligned with their respective clipping coefficients at the multipliers 10 and 12. To calculate the clipping coefficients, the I and Q input components are tapped and each supplied to a respective multiplier (18 and 20). Each of the multipliers 18 and 20 squares the signal that it receives. The squared I and Q components are added at 22 and the square root of this sum is calculated at 24. The square root is then supplied to a comparator 26 and a divider 28.

A register 30 contains a clipping level for the clipping process. The clipping level is rewritable as required and corresponds to the maximum attainable amplitude which is set for the clipping process. At divider 28, the clipping level is divided by the square root supplied by element 24. The result is passed to a switch 32. The switch 32 operates to supply either the output of divider 28 or the value of a constant held in a register 34 as a clipping coefficient to be used by both of multipliers 10 and 12. The operation of switch 32 is controlled by the output of comparator 26. Comparator 26 compares the square root from element 24 with the clipping level from register 30. If the square root exceeds the clipping level, then the switch operates to supply the constant as the clipping coefficients. Otherwise, the output of divider 28 is supplied as the clipping coefficients.

Although the embodiment uses a digital signal processor to perform the digital domain clipping and predistortion processes, it would be apparent to the skilled person that other devices, such as a FPGA, could be used for this role.

1. Apparatus for conditioning an input signal to an amplifier, comprising signal processing means for operating on the input signal in the digital domain, wherein the signal processing means is arranged to predistort the input signal and is also arranged to clip the input signal.

2. Apparatus according to claim 1, wherein the signal processing means is arranged to clip the power of the input signal.

3. Apparatus according to claim 1 or 2, wherein the clipping is performed on the input signal in cartesian format.

4. Apparatus according to claim 1, 2 or 3, wherein the maximum amount of clipping is selectable.

5. Apparatus according to any preceding claim, further comprising delay means for delaying the input signal whilst the amount clipping is calculated by the signal processing means so that the clipping is time-aligned with the input signal when applied thereto.

6. Apparatus according to claim 5, wherein the input signal delay is implemented by the signal processing means.

7. Apparatus according to any preceding claim, wherein the input signal is a RF signal and the apparatus further comprises means for downconverting the input signal's frequency before the signal processing means operates on the input signal.

8. Apparatus according to any preceding claim, wherein the apparatus further comprises means for upconverting the input signal's frequency after the signal processing means has operated on the input signal.

9. Apparatus according to any preceding claim, wherein the signal processing means comprises a digital signal processor.

10. Apparatus according to any preceding claim, wherein the signal processing means comprises a programmable logic device such as a FPGA.

11. A telecommunications base station comprising the signal conditioning apparatus of any preceding claim.

12. Apparatus for conditioning an input signal to an amplifier, substantially as hereinbefore described with reference to the accompanying figures.
